(19) United States
(12) Patent Application Publication
(10) Pub. No.: US 2015/0114690 A1
(43) Pub. Date: Apr. 30, 2015

(54) FLEX-RIGID WIRING BOARD AND METHOD FOR MANUFACTURING FLEX-RIGID WIRING BOARD

(71) Applicant: IBIDEN Co., Ltd., Ogaki-shi (JP)

(72) Inventors: Teruyuki ISHIHARA, Ogaki-shi (JP); Michimasa Takahashi, Ogaki-shi (JP); Takashi Kariya, Ogaki-shi (JP)

(73) Assignee: IBIDEN Co., Ltd., Ogaki-shi (JP)

(21) Appl. No.: 14/522,768

(22) Filed: Oct. 24, 2014

(30) Foreign Application Priority Data
Oct. 24, 2013 (JP) 2013-221396

(51) Int. Cl. H05K 1/02; H05K 3/46; H05K 3/10; H05K 1/11

(52) U.S. Cl. CPC H05K 1/028; H05K 1/112; H05K 1/118; H05K 1/0298; H05K 3/4611; H05K 3/10
USPC 174/251; 156/280

(57) ABSTRACT

A flex-rigid wiring board includes a flexible substrate, a non-flexible substrate positioned such that the non-flexible substrate is extending in horizontal direction of the flexible substrate, a first wiring layer on first surface sides of the flexible and non-flexible substrates, a second wiring layer on second surface sides of the flexible and non-flexible substrates, a first insulating layer covering the first sides of the flexible and non-flexible substrates and having an opening exposing a portion of the first side of the flexible substrate, and a second insulating layer covering the second sides of the flexible and non-flexible substrates and having an opening exposing a portion of the second side of the flexible substrate. The first wiring layer includes first conductor pattern on the first side of the flexible substrate, and the second wiring layer includes second conductor pattern extending across the second sides of the flexible and non-flexible substrates.

### CROSS-REFERENCE TO RELATED APPLICATIONS

The present application is based upon and claims the benefit of priority to Japanese Patent Application No. 2013-221396, filed Oct. 24, 2013, the entire contents of which are incorporated herein by reference.

### BACKGROUND OF THE INVENTION

1. Field of the Invention

The present invention relates to a bendable flex-rigid wiring board of which a portion is formed from a flex substrate and a manufacturing method thereof.

2. Description of Background Art

A flex-rigid wiring board of which a portion of a substrate has rigidity and another portion of the substrate has flexibility is described, for example, in Japanese Patent No. 4021472. The entire contents of this publication are incorporated herein by reference.

### SUMMARY OF THE INVENTION

According to one aspect of the present invention, a flex-rigid wiring board includes a flexible substrate, a non-flexible substrate positioned such that the non-flexible substrate is extending in a horizontal direction of the flexible substrate, a first wiring layer formed on first surface sides of the flexible substrate and non-flexible substrate, a second wiring layer formed on second surface sides of the flexible substrate and non-flexible substrate, a first insulating layer covering the first surface side of the flexible substrate and the first surface side of the non-flexible substrate and having an opening portion exposing at least a portion of the first surface side of the flexible substrate, and a second insulating layer covering the second surface side of the flexible substrate and the second surface side of the non-flexible substrate and having an opening portion exposing at least a portion of the second surface side of the flexible substrate. The first wiring layer includes a first conductor pattern formed on the first surface side of the flexible substrate, and the second wiring layer includes a second conductor pattern extending across the second surface side of the flexible substrate and the second surface side of the non-flexible substrate.

According to another aspect of the present invention, a method for manufacturing a flex-rigid wiring board includes positioning a flexible substrate and a non-flexible substrate such that the non-flexible substrate is extending in a horizontal direction of the flexible substrate, forming a first wiring layer on first surface sides of the flexible substrate and non-flexible substrate such that the first wiring layer includes a first conductor pattern formed on the first surface side of the flexible substrate, forming a second wiring layer on second surface sides of the flexible substrate and non-flexible substrate such that the second wiring layer includes a second conductor pattern extending across the second surface side of the flexible substrate and the second surface side of the non-flexible substrate, forming a first insulating layer on the first surface sides of the flexible substrate and non-flexible substrate such that the first insulating layer covers the first surface side of the flexible substrate and the first surface side of the non-flexible substrate and has an opening portion exposing at least a portion of the first surface side of the flexible substrate; and forming a second insulating layer on the second surface sides of the flexible substrate and non-flexible substrate such that the second insulating layer covers the second surface side of the flexible substrate and the second surface side of the non-flexible substrate and has an opening portion exposing at least a portion of the second surface side of the flexible substrate.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 illustrates a cross-sectional view of a flex-rigid wiring board according to a first embodiment of the present invention;

FIG. 2(A)-2(C) illustrate manufacturing process diagrams of the flex-rigid wiring board of the first embodiment;

FIGS. 3(A) and 3(B) illustrate manufacturing process diagrams of the flex-rigid wiring board of the first embodiment;

FIGS. 4(A) and 4(B) illustrate manufacturing process diagrams of the flex-rigid wiring board of the first embodiment;

FIG. 5(A)-5(C) illustrate manufacturing process diagrams of the flex-rigid wiring board of the first embodiment;

FIG. 6(A)-6(C) illustrate manufacturing process diagrams of the flex-rigid wiring board of the first embodiment;

FIGS. 7(A) and 7(B) illustrate manufacturing process diagrams of the flex-rigid wiring board of the first embodiment;

FIGS. 8(A) and 8(B) illustrate manufacturing process diagrams of the flex-rigid wiring board of the first embodiment;

FIGS. 9(A) and 9(B) illustrate manufacturing process diagrams of the flex-rigid wiring board of the first embodiment;

FIGS. 10(A) and 10(B) illustrate manufacturing process diagrams of the flex-rigid wiring board of the first embodiment;

FIG. 11(A) illustrates a plan view of the flex-rigid wiring board of the first embodiment;

FIG. 11(B) illustrates a bottom view of the flex-rigid wiring board of the first embodiment; and

FIG. 12 illustrates a cross-sectional view of a flex-rigid wiring board according to a second embodiment of the present invention.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

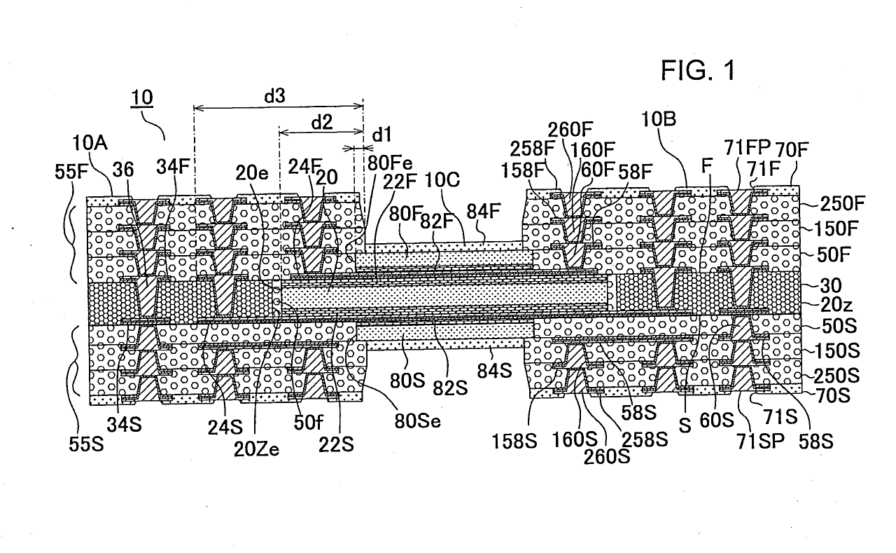

FIG. 1 illustrates a cross-sectional view of a flex-rigid wiring board according to a first embodiment.

The flex-rigid wiring board is formed from a first rigid substrate (10A) that does not have flexibility, a second rigid substrate (10B) that does not have flexibility, and a flex substrate (flexible substrate) (10C) that connects the first rigid substrate (10A) and the second rigid substrate (10B) and has flexibility. The first rigid substrate (10A) and the second rigid substrate (10B) are bendable via the flex substrate (10C). On the first rigid substrate (10A) and the second rigid substrate (10B), an arbitrary circuit pattern is formed. Further, as needed, an electronic part such as a semiconductor chip is connected.

The first rigid substrate (10A) and the second rigid substrate (10B) have a core substrate 30 that is formed by: an insulating substrate (20z) having a first surface (F) and a second surface (S) that is on an opposite side of the first surface (F); a first conductor layer (34F) that is formed on the first surface of the insulating substrate; a second conductor layer (34S) that is formed on the second surface (S) of the insulating substrate; and a via conductor 36 that connects the first conductor layer (34F) and the second conductor layer (34S). The insulating substrate has a reinforcing material such as glass cloth and organic fibers. Here, the via conductor is provided. However, in place of the via conductor, it is also possible to provide a through-hole conductor and a conductor bump.

An upper side build-up layer (55F) is formed on the first surface (F) and the first conductor layer (34F), of the core substrate 30. The upper side build-up layer at least has an uppermost interlayer resin insulating layer (250F), an uppermost conductor layer (258F) on the uppermost interlayer resin insulating layer, and an uppermost via conductor (260F) that penetrates through the uppermost interlayer resin insulating layer and electrically connects the uppermost conductor layer and a middle-layer conductor layer (158F). The upper side build-up layer further has a middle-layer interlayer resin insulating layer (150F), the middle-layer conductor layer (158F) on the middle-layer interlayer resin insulating layer, and a middle-layer via conductor (160F) that penetrates through the middle-layer interlayer resin insulating layer and electrically connects the middle-layer conductor layer and an upper side conductor layer (58F). The upper side build-up layer further has an upper side interlayer resin insulating layer (50F) between the middle-layer interlayer resin insulating layer and the core substrate, the upper side conductor layer (58F) on the upper side interlayer resin insulating layer, and an upper side via conductor (60F) that penetrates through the upper side interlayer resin insulating layer and connects the upper side conductor layer and the first conductor layer (34F) of the core substrate.

A lower side build-up layer (55S) is formed on the second surface (S) of the core substrate 30. The lower side build-up layer at least has a lowermost interlayer resin insulating layer (250S), a lowermost conductor layer (258S) on the lowermost interlayer resin insulating layer, and a lowermost via conductor (260S) that penetrates through the lowermost interlayer resin insulating layer and electrically connects the lowermost conductor layer and a middle-layer conductor layer (158S). The lower side build-up layer further has a middle-layer interlayer resin insulating layer (150S), the middle-layer conductor layer (158S) on the middle-layer interlayer resin insulating layer, and a middle-layer via conductor (160S) that penetrates through the middle-layer interlayer resin insulating layer electrically connects the middle-layer conductor layer and a lower side conductor layer (58S). The lower side build-up layer further has a lower side interlayer resin insulating layer (50S) between the middle-layer interlayer resin insulating layer (158S) and the core substrate 30, the lower side conductor layer (58S) on the lower side interlayer resin insulating layer, and a lower side via conductor (60S) that penetrates through the lower side interlayer resin insulating layer and connects the lower side conductor layer and the second conductor layer. The first surface of the core substrate and the first surface of the insulating substrate are the same surface; and the second surface of the core substrate and the second surface of the insulating substrate are the same surface.

An upper side solder resist layer (70F) is formed on the upper side build-up layer, and a lower side solder resist layer (70S) is formed on the lower side build-up layer. The solder resist layer (70F) has an opening (71F) that exposes the uppermost conductor layer and the uppermost via conductor; and the solder resist layer (70S) has an opening (71S) that exposes the lowermost conductor layer and the lowermost via conductor. Conductor portions that are exposed by the openings function as pads (71FP, 71 SP).

The flex substrate (10C) is provided with a base material 20 that is made of a polyimide sheet having a first surface (F) and a second surface (S) that is on an opposite side of the first surface, a first wiring layer (24F) that is formed via a bonding layer (22F) that is provided on the first surface side of the base material 20, and a second wiring layer (24S) that is formed via a bonding layer (22S) that is provided on the second surface side of the base material 20. A coverlay (covering layer) (80F) covers via a bonding layer (82F) on the first wiring layer (24F). A solder resist layer (84F) is formed on the coverlay (80F). A coverlay (covering layer) (80S) covers via a bonding layer (82S) on the second wiring layer (24S). A solder resist layer (84S) is formed on the coverlay (80S). The coverlays (80F, 80S) are formed from insulating films of polyimide and the like.

The coverlays (80F, 80S) enter into the first rigid substrate (10A) and the second rigid substrate (10B) for about d1 (50 μm or more). On the other hand, the base material 20 enters into the first rigid substrate (10A) and the second rigid substrate (10B) for d2 (100 μm or more). The second wiring layer (24S) enters the first rigid substrate (10A) and the second rigid substrate (10B) for d3 (150 μm or more). The entering amount (d1) of the coverlays (80F, 80S) into the first rigid substrate (10A) and the second rigid substrate (10B) is a minimum required amount for the coverlays (80F, 80S) not to be disengaged from the first rigid substrate (10A) and the second rigid substrate (10B) when a stress is applied to the flex substrate. There is a gap between an end part (20e) of the base material 20 and an end part (20Ze) of the insulating substrate (20z). Resin (50f) is filled in the gap.

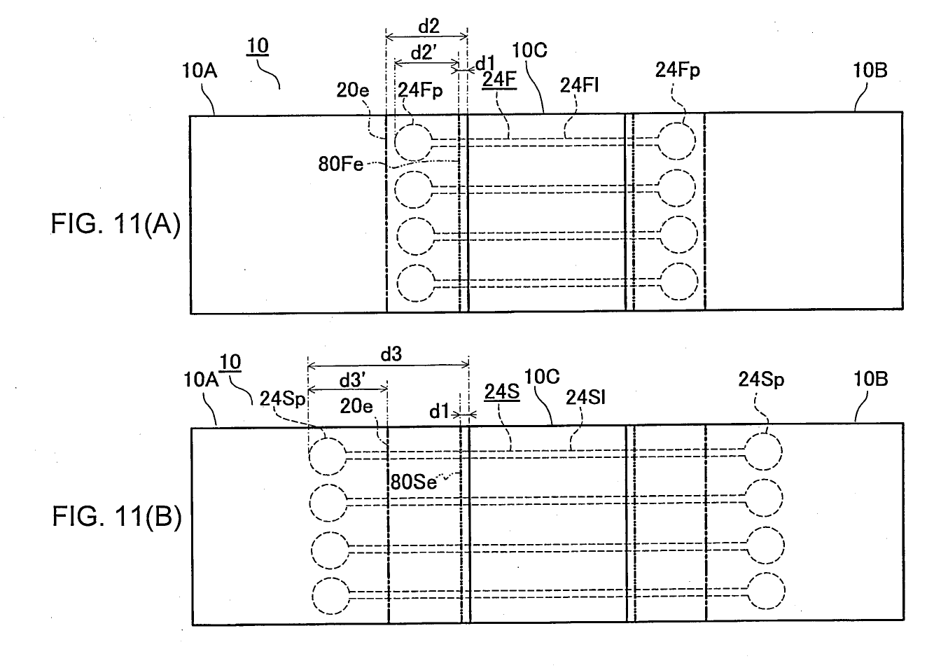

FIG. 11A illustrates a plan view of a flex-rigid wiring board 10.

The first wiring layer (24F) is formed from pad parts (24Fp) that connect to the via conductor (60F) that is formed on the upper side interlayer resin insulating layer (50F) of the first rigid substrate (10A) and the second rigid substrate (10B), and line parts (24Fl) that each connect the pad parts (24Fp) (pad part (24Fp)—pad part (24Fp)) at two ends. The first wiring layer (24F) is exposed for a length (d2′) from an end part (80Fe) of the coverlay (80F). The length (d2′) corresponds to a diameter of the pad part (24Fp) and a portion of a length of the line part (24Fl).

FIG. 11B illustrates a bottom view of the flex-rigid wiring board 10.

The second wiring layer (24S) is formed from pad parts (24Sp) that connect to the via conductor (60S) that is formed on the lower side interlayer resin insulating layer (50S) of the first rigid substrate (10A) and the second rigid substrate (10B), and line parts (24Sl) that each connect the pad parts (24Sp) (pad part (24Sp)—pad part (24Sp)) at two ends. The second wiring layer (24S) is exposed for a length (d3′) from the end part (20e) of the base material 20. The length (d3′) corresponds to a diameter of the pad part (24Sp) and a portion of a length of the line part (24Sl).

In the flex-rigid wiring board of the first embodiment, the pad parts (24Fp) of the first wiring layer (24F) are exposed from the coverlay (80F), and the via conductor (60F) that penetrates through the upper side interlayer resin insulating layer (50F) connects to the pad parts (24Fp). Further, the pad parts (24Sp) of the second wiring layer (24S) are exposed from the coverlay (80S), and the via conductor 36 that is provided in the core substrate connects to the pad parts (24Sp). That is, the via conductors (60F, 60S) do not penetrate through the coverlay and the interlayer resin insulating layer, but only penetrate through the interlayer resin insulating layer. Therefore, the pad parts of the via conductor can be miniaturized and the flex-rigid wiring board can be formed to have a fine pitch. Without penetrating through the coverlay, the via conductor penetrates through only the interlayer resin insulating layer. Therefore, the coverlay does not significantly enter into the rigid substrates so that interlayer variations of the rigid substrates are reduced, and further, restriction in wiring design in order to avoid the coverlay is reduced.

The second wiring layer (24S) is exposed (extended) for the length (d3′) from the end part (20e) of the base material 20. Therefore, direct connection by the via conductor 36 that is provided in the core substrate 30 to the pad parts (24Sp) of the second wiring layer (24S) is possible. Therefore, a wiring length between the second wiring layer (24S) and the first surface side of the first rigid substrate (1 OA) and the second rigid substrate (10B) can be shortened. Here, similar to the second wiring layer (24S), the first wiring layer (24F) may be extended from the end part 20e of the base material 20.

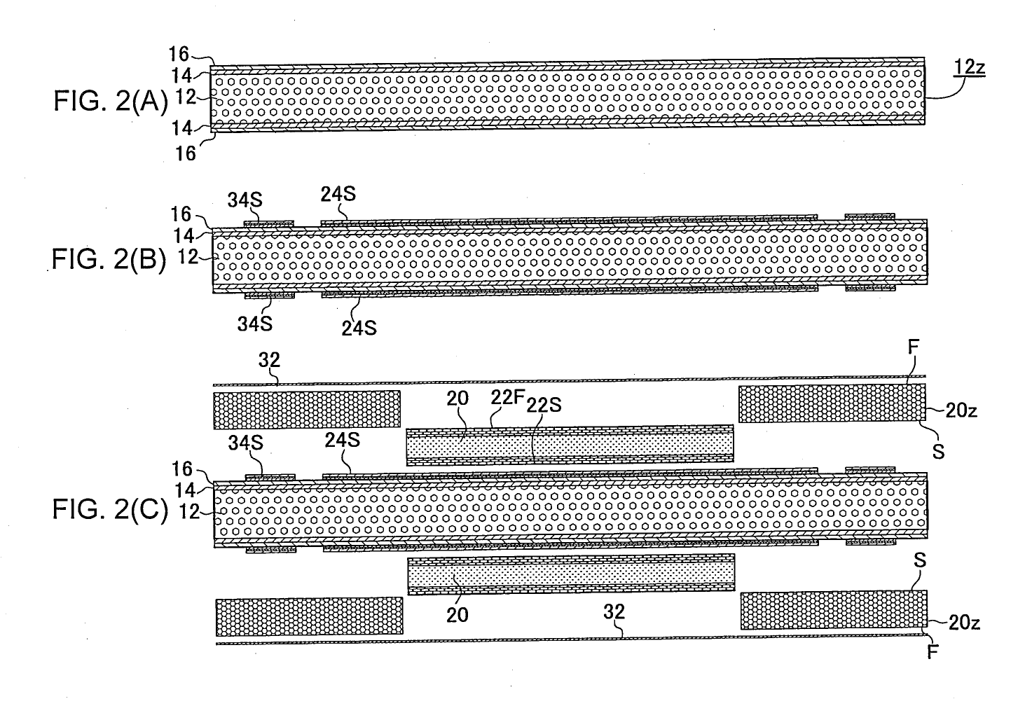

FIG. 2-10 illustrate a manufacturing process of a flex-rigid wiring board of the first embodiment. A method for manufacturing the flex-rigid wiring board 10 is described in the following.

(1) A copper foil 16 is laminated on a copper foil of a carrier (12z) that is formed from a double-sided copper-clad laminated plate that is formed by laminating copper foils 14 on both sides of an insulating base material 12 (FIG. 1A).

(2) A plating layer is formed on the copper foil 16; a resist mask (not illustrated in the drawings) is formed to perform patterning; and the second wiring layer (24S) and the second conductor layer (34S) that are illustrated in FIG. 11B are formed (FIG. 1B).

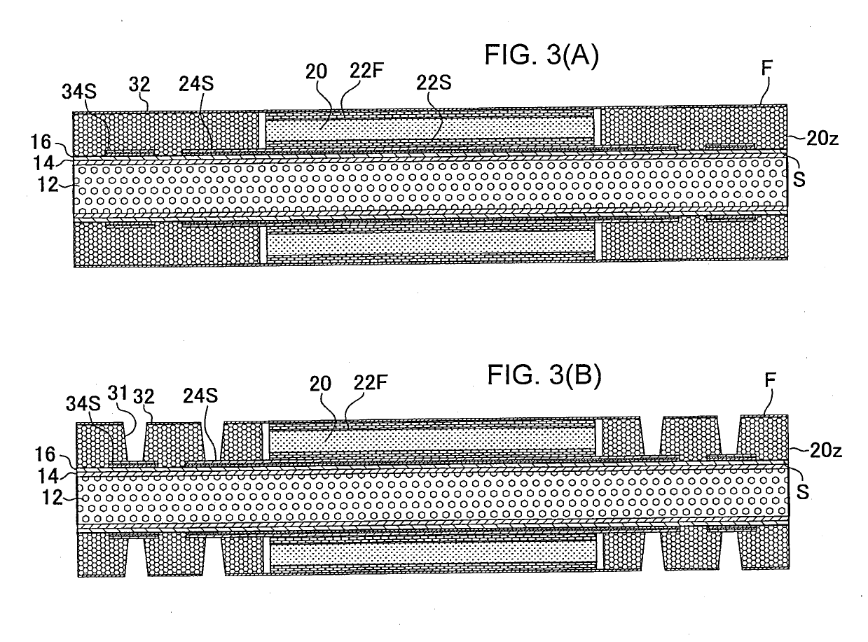

(3) On a central part of the second conductor layer (34S), a base material 20, on both sides of which bonding layers (22F, 22S) are provided, is arranged; on two end parts of the insulating base material 12, an insulating substrate (20z) that is formed from prepreg and forms a core substrate of a first rigid substrate, is arranged; and further, a copper foil 32 is arranged (FIG. 2C). These are laminated (FIG. 3A). In this process, the second wiring layer (24S) and the second conductor layer (34S) are embedded in the bonding layer (22S) and the insulating substrate (20z).

(4) At predetermined positions of the insulating substrate (20z), openings 31 for vias are formed using laser (FIG. 3B).

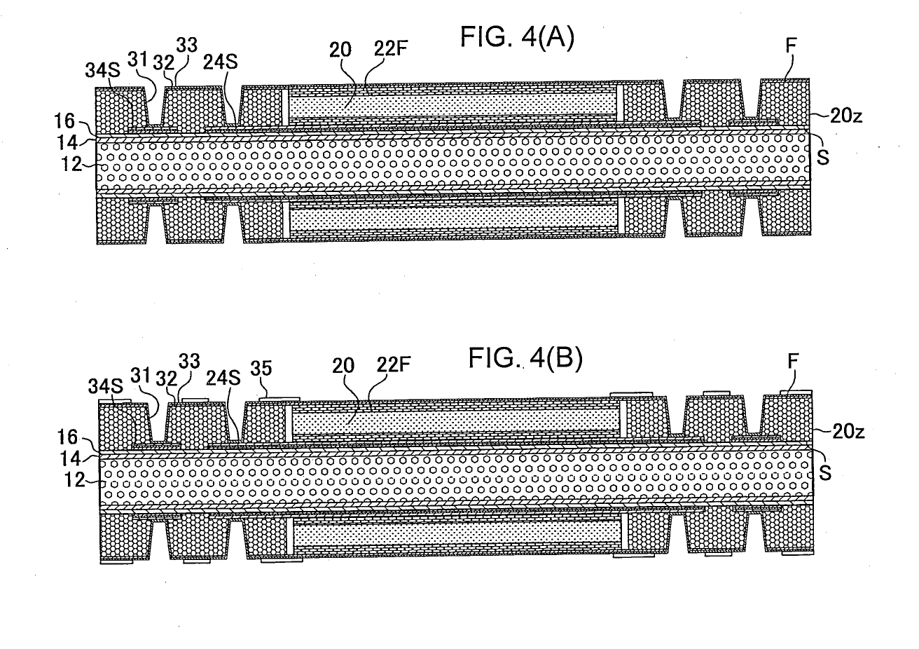

(5) An electroless plating film 33 is formed on the copper foil 32 and in the openings 31 by an electroless plating process (FIG. 4A).

(6) A plating resist 35 of a predetermined pattern is formed on the electroless plating film 33 (FIG. 4B).

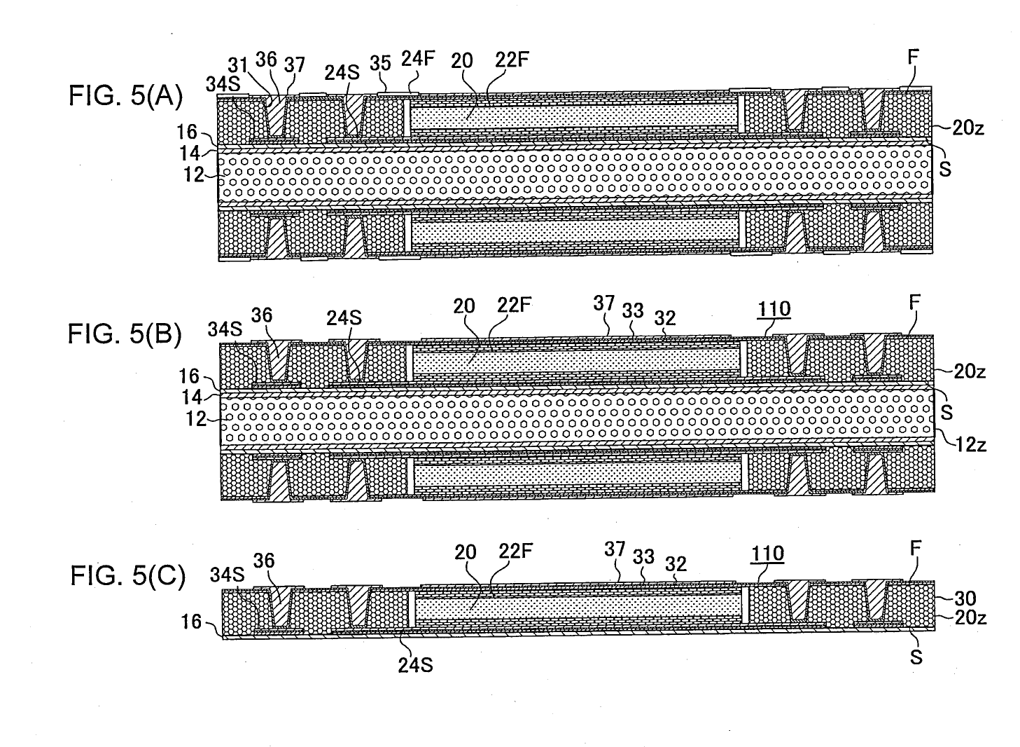

(7) By an electrolytic plating process, an electrolytic plating film 37 is formed in a non-forming part of the plating resist 35, and a via conductor 36 is formed by the electrolytic plating film in the opening 31 (FIG. 5A).

(8) The plating resist is peeled off (FIG. 5B).

(9) An intermediary body 110 that is formed from the insulating substrate (20z) and the base material 20 is separated from the carrier 12z (FIG. 5C).

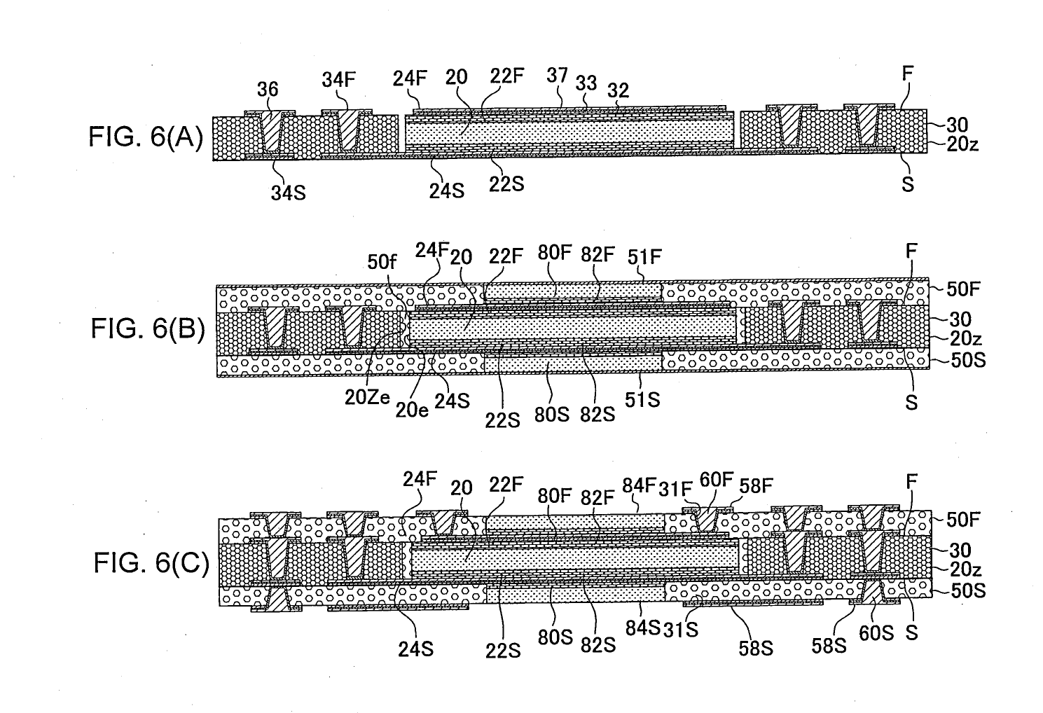

(10) The electroless plating film 33 and the copper foil 32 that are exposed from the electrolytic plating film 37 on the first surface (F) side are removed by etching, and a first wiring layer (24F) and a first conductor layer (34F) that are formed from the electrolytic plating film 37, the electroless plating film 33 and the copper foil 32 are formed. Further, on the second surface (S) side, the copper foil 16 is removed, and the second wiring layer (24S) and the second conductor layer (34S) are exposed (FIG. 6A). The first wiring layer (24F) and the first conductor layer (34F) are exposed from the insulating substrate (20z) and the bonding layer (22F). The second wiring layer (24S) and the second conductor layer (34S) are embedded in the insulating substrate (20z) and the bonding layer (22S).

(12) A coverlay (80F) is laminated via a bonding layer (82F) on a central part of the first wiring layer (24F); a coverlay (80S) is laminated via a bonding layer (82S) on a central part of the second wiring layer (24S); an interlayer resin insulating layer (50F) that is formed from prepreg is laminated on the first surface (F) side of the insulating substrate (20z) and end parts of the first wiring layer (24F); an interlayer resin insulating layer (50S) that is formed from prepreg is laminated on the second surface (S) side of the insulating substrate (20z) and end parts of the second wiring layer (24S); and further, copper foils (51F, 51S) are laminated (FIG. 6B). Resin (50f) that exudes from the interlayer resin insulating layer (50F) is filled in a gap between an end part (20e) of the base material 20 and an end part (20Ze) of the insulating substrate (20z).

(13) At predetermined positions of the interlayer resin insulating layer (50F), openings (31F) for vias are formed using laser; openings (31S) are formed in the interlayer resin insulating layer (50S); in processes similar to (5)-(10), an electroless plating film is formed; a plating resist is formed; an electrolytic plating film is formed in a non-forming part of the plating resist; after peeling off the plating resist, the electroless plating film and the copper foils in the non-forming part of the electrolytic plating film are removed; and via conductors (60F, 60S) and conductor layers (58F, 58S) are formed (FIG. 6C).

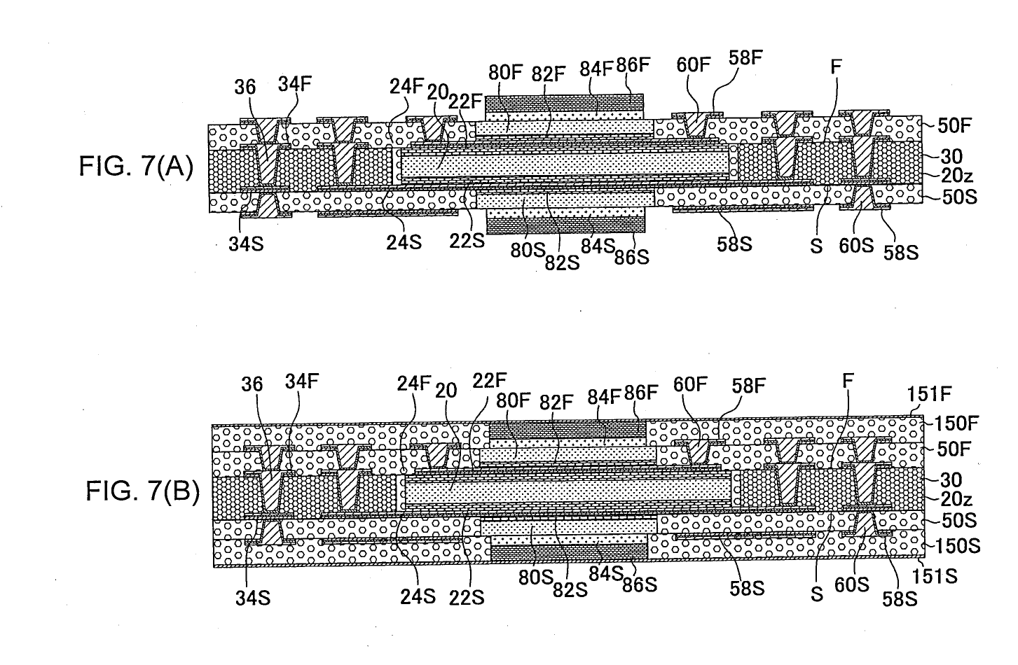

(14) A solder resist layer (84F) is formed on the coverlay (80F), and further, a release layer (86F) is formed on the solder resist layer (84F). Similarly, a solder resist layer (84S) is formed on the coverlay (80S), and further, a release layer (86S) is formed on the solder resist layer (84S) (FIG. 7A).

(15) An interlayer resin insulating layer (150F) is provided in a horizontal direction of the solder resist layer (84F) and the release layer (86F); an interlayer resin insulating layer (150S) is provided in a horizontal direction of the solder resist layer (84S) and the release layer (86S); and copper foils (151F, 151S) are laminated on the interlayer resin insulating layers (FIG. 7B).

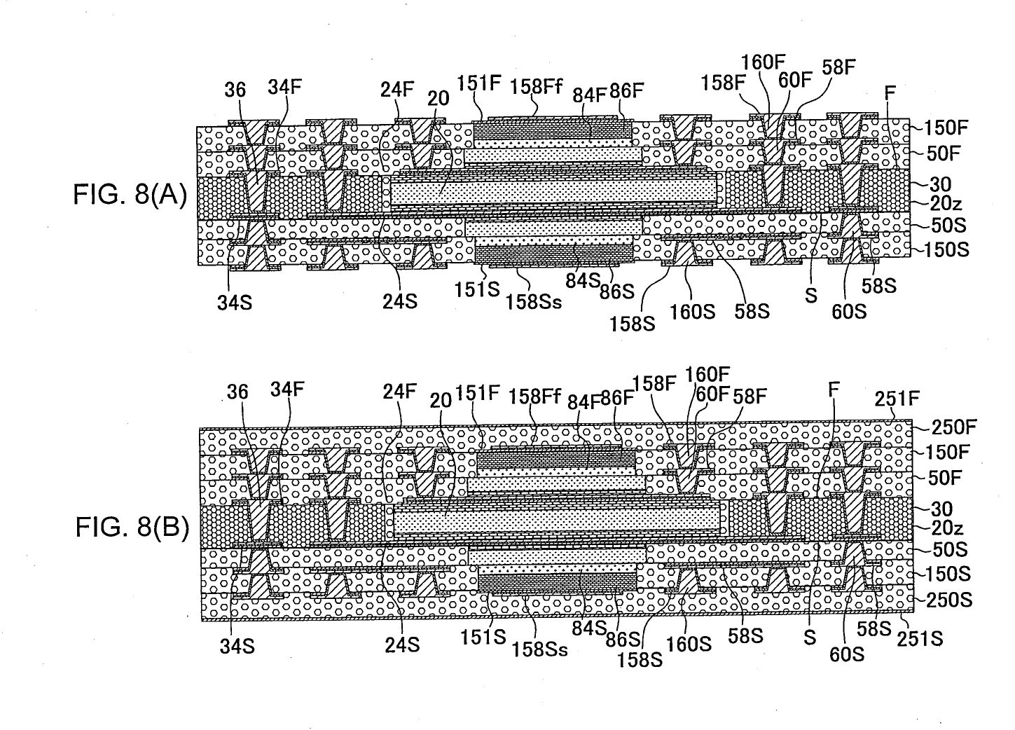

(16) Similar to the process in which FIG. 6C is referenced, conductor layers (158F, 158S) are formed on the interlayer resin insulating layers (150F, 150S), and further, via conductors (160F, 160S) that penetrate through the interlayer resin insulating layers (150F, 150S) are formed. On the release layers (86F, 86S), release conductors (158Ff, 158Ss) are formed in a state in which the copper foil (151F) is exposed at end parts (FIG. 8A).

(17) On the interlayer resin insulating layers (150F, 150S) and on the release conductors (158Ff, 158Ss), interlayer resin insulating layers (250F, 250S) and copper foils (251F, 251S) are laminated (FIG. 8B).

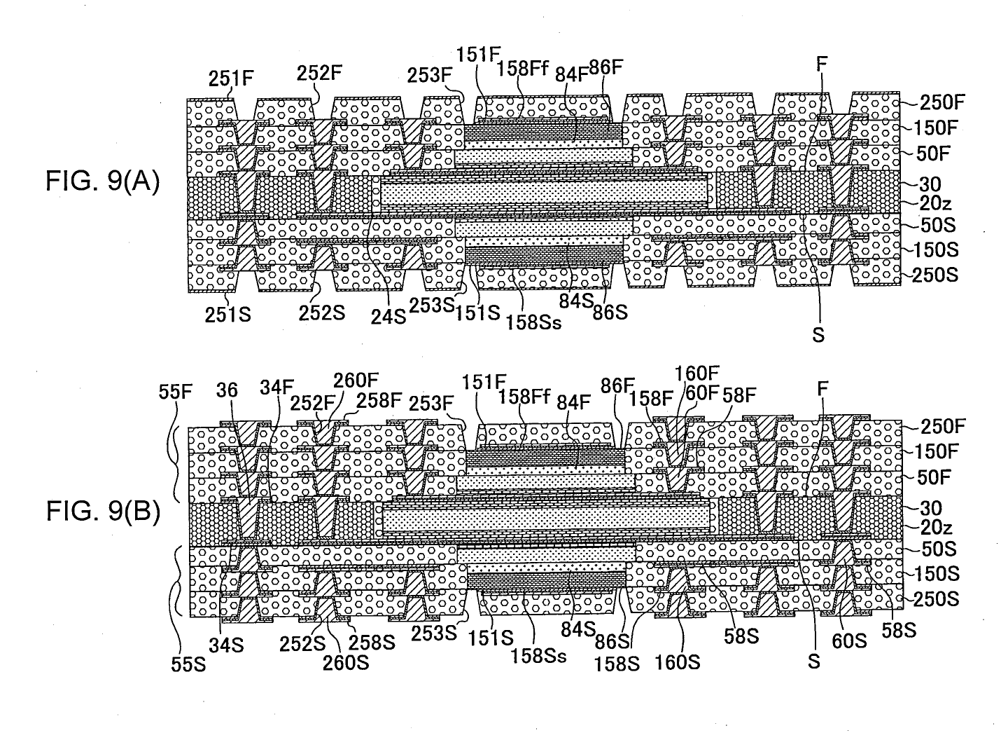

(18) At predetermined positions of the interlayer resin insulating layers (250F, 250S), openings (252F, 252S) for vias are formed using laser; and at the same time, cut openings (253F, 253S) having a rectangular shape in plan view reaching the copper foil (151F) of outer peripheries of the release conductors (158Ff, 158Ss) are formed (FIG. 9A).

(19) Similar to the process in which FIG. 6C is referenced, conductor layers (258F, 258S) are formed on the interlayer resin insulating layers (250F, 250S), and further, via conductors (260F, 260S) that penetrate through the interlayer resin insulating layers (250F, 250S) are formed. The copper foil (151F) at lower ends of the cut openings (253F, 253S) is removed and the release layers (86F, 86S) are exposed (FIG. 9B).

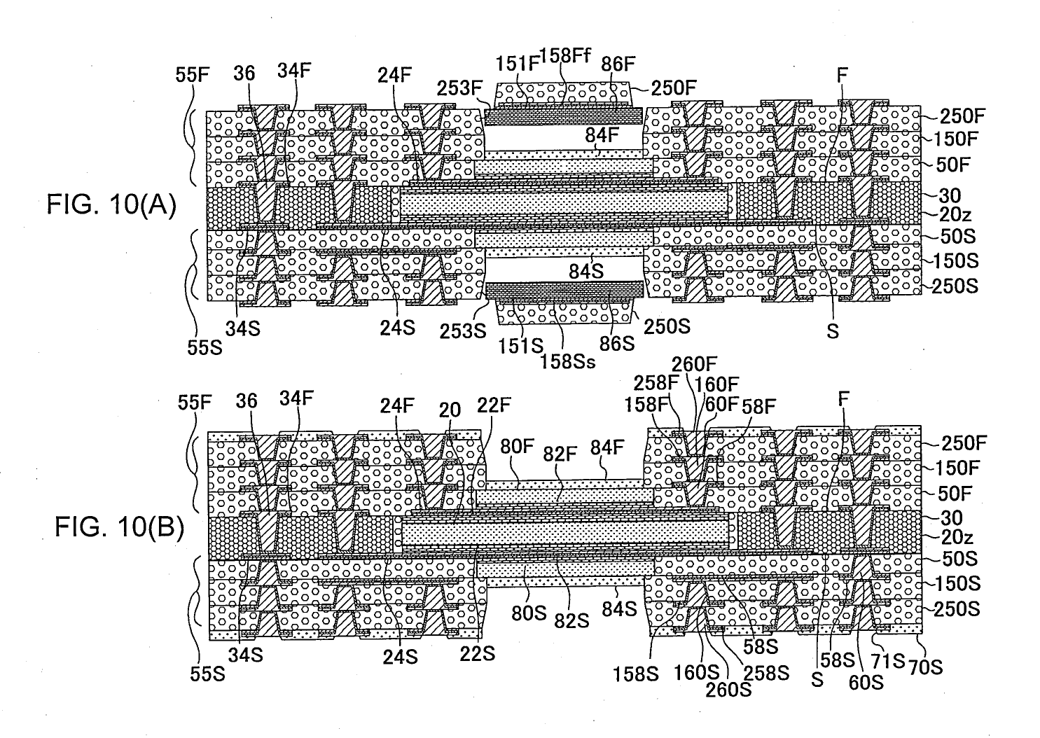

(20) The release layers (86F, 86S) and the interlayer resin insulating layers (250F, 250S), on the solder resist layers (84F, 84S), are removed (FIG. 10A).

(21) An upper side solder resist layer (70F) is formed on the upper side build-up layer, and a lower side solder resist layer (70S) is formed on the lower side build-up layer (FIG. 10B). The solder resist layer (70F) has an opening (71F) that exposes the uppermost conductor layer and the uppermost via conductor; and the solder resist layer (70S) has an opening (71S) that exposes the lowermost conductor layer and the lowermost via conductor. In the openings (71F, 71S), a nickel plating layer and a gold plating layer are formed (not illustrated in the drawings). Other than the nickel-gold layers, nickel-palladium-gold layers and an OSP coating film may also be formed.

Unlike a completed flex substrate sandwiched by interlayer resin insulating layers of rigid substrates, in the first embodiment, the flex substrate and the rigid substrates are simultaneously built up on the carrier (12z). Therefore, it is possible to adopt a configuration in which the via conductors (60F, 60S) do not penetrate the coverlay and the interlayer resin insulating layer, but only penetrate the interlayer resin insulating layer. As a result, the pad parts of the via conductor can be miniaturized and the flex-rigid wiring board can be formed to have a fine pitch. Without penetrating through the coverlay, the via conductor penetrates through only the interlayer resin insulating layer. Therefore, the coverlay does not significantly enter into the rigid substrates so that interlayer variations of the rigid substrates are reduced, and further, restriction in wiring design in order to avoid the coverlay is reduced.

### Second Embodiment

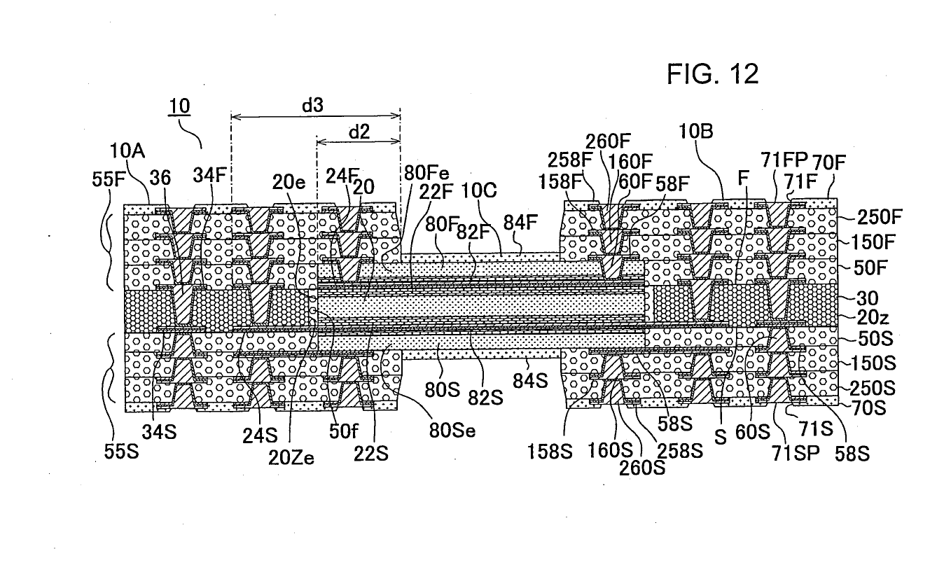

FIG. 12 illustrates a cross-sectional view of a flex-rigid wiring board according to a second embodiment of the present invention.

In the second embodiment, the coverlays (80F, 80S) cover the entire flex substrate (10C). In the second embodiment, the conductor pattern (24S) of the base material 20 and a portion of the conductor pattern (34S) of the rigid substrates (10A, 10B) are continuously formed. Therefore, a conductor pattern of a rigid wiring board and a conductor pattern of a flex wiring board can be directly connected without using a via, and a wiring path can be shortened. Without a connection pad of a via and the like, high density wiring becomes possible.

A via conductor that connects the flex substrate and the rigid substrates is provided in a cover layer of wiring of the flex substrate. Therefore, the via conductor penetrates through an insulating layer and the cover layer that form the rigid substrates, and the via conductor becomes large in size so that it is difficult to form via conductors at a fine pitch. Further, the cover layer enters into the rigid substrates. Therefore, interlayer variations of the rigid substrates become large, and further, wiring design is subject to restrictions in order to avoid the cover layer.

A flex-rigid wiring board according to an embodiment of the present invention and a method for manufacturing the flex-rigid wiring board according to an embodiment of the present invention are capable of allowing fine pitch formation.

A flex-rigid wiring board according to an embodiment of the present invention includes: a flexible substrate that is provided with a primary surface and a secondary surface that is on an opposite side of the primary surface, and has a primary surface side conductor pattern and a secondary surface side conductor pattern; a non-flexible substrate that is arranged in a horizontal direction of the flexible substrate, is provided with the primary surface and the secondary surface, and has a primary surface side conductor pattern and a secondary surface side conductor pattern; and a pair of insulating layers that sandwich the primary surface of the flexible substrate and the primary surface of the non-flexible substrate and the secondary surface of the flexible substrate and the secondary surface of the non-flexible substrate, and expose at least a portion of the flexible substrate. The primary surface side conductor pattern of the flexible substrate and a portion of the primary surface side conductor pattern of the non-flexible substrate are continuously formed.

In a flex-rigid wiring board according to an embodiment of the present invention, the primary surface side conductor pattern of the flexible substrate and a portion of the primary surface side conductor pattern of the non-flexible substrate are continuously formed. Therefore, a conductor pattern of a rigid wiring board and a conductor pattern of a flex wiring board can be directly connected without using a via, and a wiring path can be shortened. Without a connection pad of a via and the like, high density wiring becomes possible. Further, a configuration can be adopted in which, on another portion of a conductor pattern that is covered by an insulating layer without being covered by a covering layer, a via that penetrates through the insulating layer is connected. That is, the via does not penetrates through the covering layer and the insulating layer, but only penetrates through the insulating layer. Therefore, the via can be miniaturized, and the flex-rigid wiring board can be formed to have a fine pitch. Since the via penetrates through only the insulating layer without penetrating through the covering layer, the covering layer does not significantly enter into the rigid substrates so that interlayer variations of the rigid substrates are reduced, and further, restriction in wiring design in order to avoid the covering layer is reduced.

Obviously, numerous modifications and variations of the present invention are possible in light of the above teachings. It is therefore to be understood that within the scope of the appended claims, the invention may be practiced otherwise than as specifically described herein.

What is claimed is:

1. A flex-rigid wiring board, comprising:
a flexible substrate;
a non-flexible substrate positioned such that the non-flexible substrate is extending in a horizontal direction of the flexible substrate;
a first wiring layer formed on first surface sides of the flexible substrate and non-flexible substrate;
a second wiring layer formed on second surface sides of the flexible substrate and non-flexible substrate;
a first insulating layer covering the first surface side of the flexible substrate and the first surface side of the non-flexible substrate and having an opening portion exposing at least a portion of the first surface side of the flexible substrate; and
a second insulating layer covering the second surface side of the flexible substrate and the second surface side of the non-flexible substrate and having an opening portion exposing at least a portion of the second surface side of the flexible substrate,
wherein the first wiring layer includes a first conductor pattern formed on the first surface side of the flexible substrate, and the second wiring layer includes a second conductor pattern extending across the second surface side of the flexible substrate and the second surface side of the non-flexible substrate.

2. The flex-rigid wiring board according to claim 1, wherein the flexible substrate and the non-flexible substrate have second surfaces on the second surface sides such that the second surfaces of the flexible substrate and the non-flexible substrate form a same plane.

3. The flex-rigid wiring board according to claim 1, wherein the flexible substrate and the non-flexible substrate have second surfaces on the second surface sides such that the second surfaces of the flexible substrate and the non-flexible substrate form a same plane, and the second conductor pattern of the second wiring layer forms the same plane.

4. The flex-rigid wiring board according to claim 1, wherein the flexible substrate and the non-flexible substrate are positioned such that a gap is formed between the flexible substrate and the non-flexible substrate, and the gap between the flexible substrate and the non-flexible substrate is filled by a resin material.

5. The flex-rigid wiring board according to claim 1, further comprising:
a coverlay layer formed in the opening portion of the second insulating layer such that the coverlay layer is covering a portion of the second wiring layer on the second surface side of the flexible substrate.

6. The flex-rigid wiring board according to claim 2, further comprising:
a coverlay layer formed in the opening portion of the second insulating layer such that the coverlay layer is covering a portion of the second wiring layer on the second surface side of the flexible substrate.

7. The flex-rigid wiring board according to claim 3, further comprising:
a coverlay layer formed in the opening portion of the second insulating layer such that the coverlay layer is covering a portion of the second wiring layer on the second surface side of the flexible substrate.

8. The flex-rigid wiring board according to claim 4, further comprising:
a coverlay layer formed in the opening portion of the second insulating layer such that the coverlay layer is covering a portion of the second wiring layer on the second surface side of the flexible substrate.

9. The flex-rigid wiring board according to claim 1, further comprising:
a coverlay layer formed in the opening portion of the second insulating layer such that the coverlay layer is covering a portion of the second wiring layer on the second surface side of the flexible substrate; and
a via conductor connected to a portion of the second wiring layer on the second surface side of the non-flexible substrate.

10. The flex-rigid wiring board according to claim 2, further comprising:
a coverlay layer formed in the opening portion of the second insulating layer such that the coverlay layer is covering a portion of the second wiring layer on the second surface side of the flexible substrate; and
a via conductor connected to a portion of the second wiring layer on the second surface side of the non-flexible substrate.

11. The flex-rigid wiring board according to claim 3, further comprising:
a coverlay layer formed in the opening portion of the second insulating layer such that the coverlay layer is covering a portion of the second wiring layer on the second surface side of the flexible substrate; and
a via conductor connected to a portion of the second wiring layer on the second surface side of the non-flexible substrate.

12. The flex-rigid wiring board according to claim 4, further comprising:
a coverlay layer formed in the opening portion of the second insulating layer such that the coverlay layer is covering a portion of the second wiring layer on the second surface side of the flexible substrate; and
a via conductor connected to a portion of the second wiring layer on the second surface side of the non-flexible substrate.

13. The flex-rigid wiring board according to claim 1, wherein the second conductor pattern of the second wiring layer includes a plurality of second pad portions formed on the second surface side of the non-flexible substrate and a plurality of second line portions formed on the second surface side of the flexible substrate such that the second line portions extend and are connected to the second pad portions, respectively.

14. The flex-rigid wiring board according to claim 13, further comprising:
a coverlay layer formed in the opening portion of the second insulating layer such that the coverlay layer is covering a portion of the second wiring layer on the second surface side of the flexible substrate.

15. The flex-rigid wiring board according to claim 13, further comprising:
a plurality of via conductors formed in the non-flexible substrate such that the via conductors are connected to the second pad portions of the second wiring layer on the second surface side of the non-flexible substrate, respectively.

16. A method for manufacturing a flex-rigid wiring board, comprising:
positioning a flexible substrate and a non-flexible substrate such that the non-flexible substrate is extending in a horizontal direction of the flexible substrate;
forming a first wiring layer on first surface sides of the flexible substrate and non-flexible substrate such that the first wiring layer includes a first conductor pattern formed on the first surface side of the flexible substrate;
forming a second wiring layer on second surface sides of the flexible substrate and non-flexible substrate such that the second wiring layer includes a second conductor pattern extending across the second surface side of the flexible substrate and the second surface side of the non-flexible substrate;
forming a first insulating layer on the first surface sides of the flexible substrate and non-flexible substrate such that the first insulating layer covers the first surface side of the flexible substrate and the first surface side of the non-flexible substrate and has an opening portion exposing at least a portion of the first surface side of the flexible substrate; and
forming a second insulating layer on the second surface sides of the flexible substrate and non-flexible substrate such that the second insulating layer covers the second surface side of the flexible substrate and the second surface side of the non-flexible substrate and has an opening portion exposing at least a portion of the second surface side of the flexible substrate.

17. The method for manufacturing a flex-rigid wiring board according to claim 16, wherein the forming of the second wiring layer comprises forming on a support plate the second wiring layer comprising the second conductor pattern, and the positioning of the flexible substrate and non-flexible substrate comprises positioning on the support plate the flexible substrate and non-flexible substrate such that the non-flexible substrate is extending in the horizontal direction of the flexible substrate.

18. The method for manufacturing a flex-rigid wiring board according to claim 16, further comprising:
forming a coverlay layer in the opening portion of the second insulating layer such that the coverlay layer covers a portion of the second wiring layer on the second surface side of the flexible substrate.

19. The method for manufacturing a flex-rigid wiring board according to claim 16, further comprising:
forming a coverlay layer in the opening portion of the second insulating layer such that the coverlay layer covers a portion of the second wiring layer on the second surface side of the flexible substrate; and
forming a via conductor in the second insulating layer such that the via conductor is connected to a portion of the second wiring layer on the second surface side of the non-flexible substrate.

20. The method for manufacturing a flex-rigid wiring board according to claim 16, further comprising:
forming a coverlay layer in the opening portion of the second insulating layer such that the coverlay layer covers a portion of the second wiring layer on the second surface side of the flexible substrate; and
forming a via conductor in the non-flexible substrate such that the via conductor is connected to the second conductor pattern of the second wiring layer on the second surface side of the non-flexible substrate.
